(19) United States
(12) Patent Application Publication
(10) Pub. No.: US 2024/0125837 A1
(43) Pub. Date: Apr. 18, 2024

(54) ADAPTIVE INSTRUMENT NOISE REMOVAL

(71) Applicant: Tektronix, Inc., Beaverton, OR (US)

(72) Inventor: Kan Tan, Portland, OR (US)

(73) Assignee: Tektronix, Inc., Beaverton, OR (US)

(21) Appl. No.: 18/478,556

(22) Filed: Sep. 29, 2023

Related U.S. Application Data
(60) Provisional application No. 63/413,450, filed on Oct. 5, 2022.

(51) Int. Cl. G01R 29/26; G01R 13/02

(52) U.S. Cl. CPC G01R 29/26; G01R 13/0272

(57) ABSTRACT

A test and measurement instrument includes an input configured to receive an input signal from a device under test (DUT), an output display, and one or more processors configured to execute code that causes the one or more processors to measure a noise component of the input signal, compensate the measured noise component based on the measurement population and a relative amount of noise generated by the test and measurement instrument and a total noise measurement, and produce the compensated measured noise component as a noise measurement on the output display. Methods are also described.

### CROSS-REFERENCE TO RELATED APPLICATIONS

This disclosure claims benefit of U.S. Provisional Application No. 63/413,450, titled “ADAPTIVE OSCILLOSCOPE NOISE REMOVAL,” filed on Oct. 5, 2022, the disclosure of which is incorporated herein by reference in its entirety.

### TECHNICAL FIELD

This disclosure relates to test and measurement instruments, and more particularly to techniques for reducing noise in a test and measurement instrument such as an oscilloscope.

### BACKGROUND

As communication systems move to higher speeds, the self-generated noise of a measurement instrument used to measure the communication system causes a greater negative impact to the accuracy of some measurements. For example, the latest generation of the PCIe (Peripheral Component Interconnect Express) communication system, generation 6, (PCIe Gen 6) has changed the required type of signal encoding from NRZ (Non-Return-to-Zero) coding to PAM4 (Pulse Amplitude Modulation 4-level) coding. The published PCIe Gen 6 specification is available through PCI SIG (PCI Special Interest Group). This encoding change in the specification from NRZ to PAM4 significantly reduces, by a factor of three, the vertical eye opening through which valid signals must pass. Noise of the instrument has a more significant impact on these reduced vertical eye openings of generation 6 than it did with previous generations of PCIe.

The standard for PCIe Gen. 6 requires that noise from the measuring instrument, such as an oscilloscope, be removed for particular measurements like the noise component of SNDR (Signal-to-Noise-Distortion-Ratio) and the jitter measurement. Other industry standards, such as IEEE 802.3ck (one of the Institute of Electrical and Electronics Engineers Ethernet standards for 53.125 GBaud electrical signals), also require the scope noise to be removed.

To remove the noise generated by the instrument, the amount of noise must first be determined. In standard practice, noises are modelled as Gaussian noises with normal distributions. The normal distribution is a generally accepted model for noises in practical applications based on the Central Limit Theorem. The total noise measured by an instrument receiving a signal from a Device Under Test (DUT) is the combination of noise from the instrument noise as well as the noise from the DUT, i.e.,

nₘₑₐₛ=n_{DUT}+nᵢₙₛₜᵣᵤₘₑₙₜ

Since the DUT noise and the instrument noise are un-correlated to each other, their statistical value of standard deviation has the following relationship:

σₘₑₐₛ²=σ_{DUT}²+σᵢₙₛₜᵣᵤₘₑₙₜ²

Thus, the standard deviation of the DUT noise can be determined as:

σ_{DUT}=\sqrt{σₘₑₐₛ²−σᵢₙₛₜᵣᵤₘₑₙₜ²}

When measuring the standard deviation of a random variable of a test sample, the results can vary on each sample, especially when the population used for the measurement is limited. Typically, measuring the instrument noise for PCIe testing for SNDR includes receiving approximately two-thousand samples and calculating the standard deviation of the noise. In practical cases, the σᵢₙₛₜᵣᵤₘₑₙₜ, that is, the standard deviation of the noise of the instrument, cannot be directly measured while the instrument is also receiving a signal from a DUT, because of the added noise from the DUT. Instead, the σᵢₙₛₜᵣᵤₘₑₙₜ may be characterized while there is no other input to the instrument. For example, the σᵢₙₛₜᵣᵤₘₑₙₜ may be characterized by receiving a long acquisition with no input signal, such as a few million samples. When measured over such a long acquisition, the σᵢₙₛₜᵣᵤₘₑₙₜ is generally very stable, and may be denoted as the average standard deviation of the instrument noise, σ̅ᵢₙₛₜᵣᵤₘₑₙₜ. This average standard deviation of the instrument noise varies very little from between different acquisition runs due to the nature of the large sample size. Note that the two standard deviations, the standard deviation for the particular sample σᵢₙₛₜᵣᵤₘₑₙₜ, and the average standard deviation, σ̅ᵢₙₛₜᵣᵤₘₑₙₜ, are similar to one another, but are not the same.

σᵢₙₛₜᵣᵤₘₑₙₜ≅σ̅ᵢₙₛₜᵣᵤₘₑₙₜ

As mentioned above, the σᵢₙₛₜᵣᵤₘₑₙₜ value cannot be directly measured because it is a component value of the total noise received by the instrument at each acquisition run. Instead, the σᵢₙₛₜᵣᵤₘₑₙₜ can only be approximated by the average standard deviation of the instrument, σ̅ᵢₙₛₜᵣᵤₘₑₙₜ. When the same σ̅ᵢₙₛₜᵣᵤₘₑₙₜ is used for every acquisition run, it is a constant value. But this approach does not reflect the actual amount of the variation of the σᵢₙₛₜᵣᵤₘₑₙₜ when the sample population is low.

σ_{DUT}=\sqrt{σₘₑₐₛ²−σ̅ᵢₙₛₜᵣᵤₘₑₙₜ²} (Eq. 1)

Equation 1 provides a manner to determine the standard deviation from the DUT, i.e., by taking the square root of the square of the measured standard deviation less the square of the average standard deviation of the instrument. There are two main issues when using this approach to remove the instrument noise from the measured noise. First, removing instrument noise using Equation (1) increases the variation of the standard deviation of the DUT noise determined by the instrument. For example, FIG. 1 is a graph 100 of standard deviation, in millivolts, taken from measurements from a DUT. The measured standard deviation, which includes noise from both the DUT as well as the instrument is shown as reference 102, near the top of graph 100. Also, in this example, the σ̅ᵢₙₛₜᵣᵤₘₑₙₜ was determined to be approximately 3.5 mV, as shown by reference 104. Then, using Equation 1 to subtract the σ̅ᵢₙₛₜᵣᵤₘₑₙₜ from the measured value 102, the standard deviation from the DUT would be reported as shown in reference 106. But note that the DUT noise after removing the instrument noise (reference 116) has greater variation than the variation of the measured noise (reference 112). Second, as seen in FIG. 2, when the noise from the DUT noise is small relative to the instrument noise, and the variation of the standard deviation of the measured noise is large because of limited population, some of the standard deviation of the measured noise 202 is less than the characterized instrument noise, resulting in a zero value for the standard deviation of the DUT noise after the instrument noise removal. Having a zero standard deviation, as shown by the spike 204 in in FIG. 2, is incorrect for a DUT having a non-zero amount of noise. Yet this behavior is an artifact of the way instrument noise is presently removed in measurement instruments.

Embodiments of the disclosure address these and other limitations of the present art.

### BRIEF DESCRIPTION OF THE DRAWINGS

FIG. 1 is a graph illustrating standard deviation and variation of measurements made by a conventional instrument both before and after instrument noise removal.

FIG. 2 is a histogram of the standard deviation of DUT noise after the instrument noise has been removed using the techniques of FIG. 1.

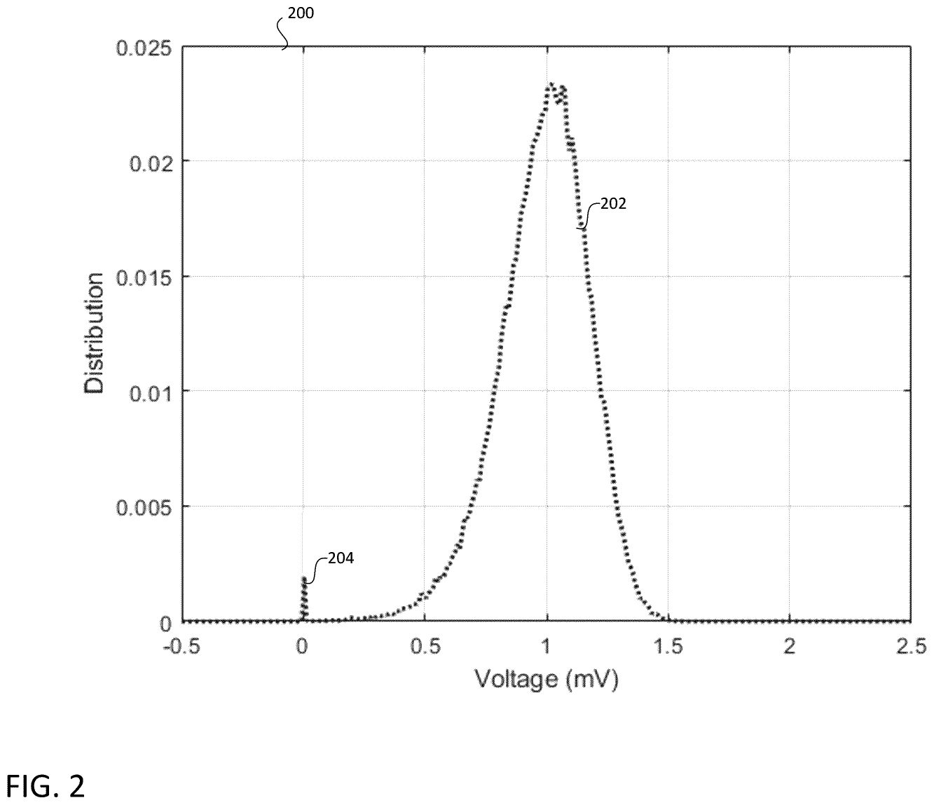

FIG. 3A is a graph illustrating distribution of standard deviation determined from 64 samples, according to embodiments of the disclosure.

FIG. 3B is a graph, in log-log scale plotting the standard deviation values compared to the sample sizes according to embodiments of the disclosure.

FIG. 4 is a graph illustrating standard deviation and variation of measurements made by a conventional instrument both before and after instrument noise removal for a larger sample size than illustrated in FIG. 1.

FIGS. 5A and 5B are graphs illustrating variation of standard deviation determined from 2048 and 8192 samples, respectively, using a conventional instrument noise removal method.

FIG. 6 is a graph illustrating a derivative of DUT noise after the instrument noise has been removed over the ratio of the average instrument noise to the measured noise, according to embodiments of the disclosure.

FIG. 7 is a graph illustrating the effect of removing instrument noise based on the amount of instrument noise removed, according to embodiments of the disclosure.

FIGS. 8A and 8B are flowcharts illustrating two different processes to remove instrument noise according to embodiments of the disclosure.

FIG. 9 is a flowchart illustrating example operations of performing adaptive instrument noise removal according to embodiments of the disclosure.

FIG. 10 is a graph illustrating the effect of modifying parameters in a modified Sigmoid function according to embodiments of the disclosure.

FIG. 11 is a graph illustrating a comparison of noise removal methods including an adaptive instrument noise removal method according to embodiments of the disclosure.

FIG. 12 is a functional block diagram of a measurement instrument, such as an oscilloscope, including adaptive instrument noise removal, according to embodiments of the disclosure.

### DESCRIPTION

Embodiments according to this disclosure are directed to an adaptive noise removal tool that more accurately measures noise originating from a DUT, and more particularly, reduces the variation of such DUT noise measurement than currently available in present measurement systems.

Table 1 shows the simulation results on the variation of the standard deviation when taking limited numbers of samples of the same random variable. For the data captured in Table 1, the random variable is generated with Gaussian distribution, with the nominal standard deviation set to 1.

TABLE 1
Sample population impact on the variation of standard deviation

| Population | Standard deviation of Std |
|---|---|
| 64 | 0.089 |
| 128 | 0.063 |
| 256 | 0.045 |
| 512 | 0.031 |
| 1024 | 0.012 |
| 2048 | 0.016 |
| 4096 | 0.011 |
| 8192 | 0.008 |

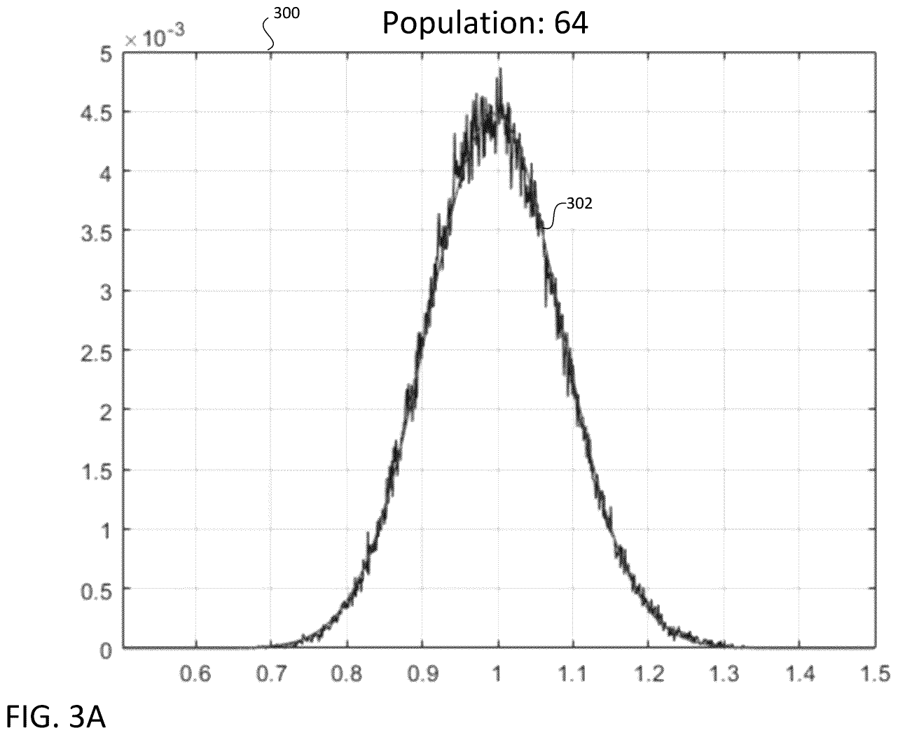

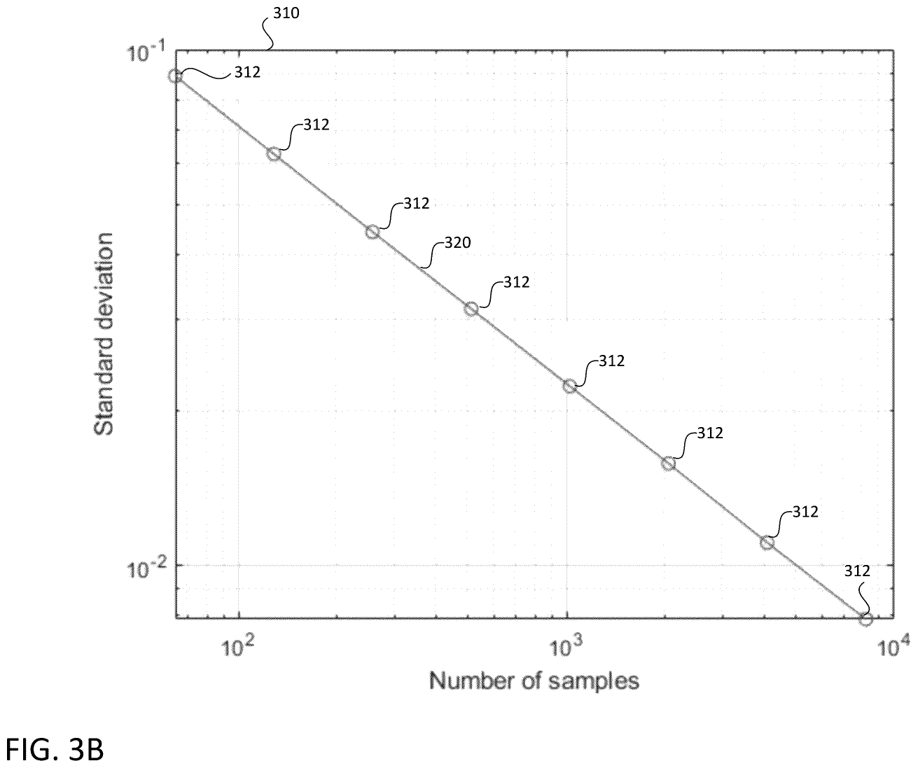

For each sample population in Table 1, the histogram of the standard deviation follows the Gaussian probability distribution function with the same standard deviation shown in the second column in Table 1. For example, FIG. 3A shows the case for the sample population of 64.

FIG. 3B is a graph 310, in log-log scale, that graphs how the standard deviation reduces as the sample size increases. Specifically, the graph 310 includes a number of data points 312 taken from Table 1, plotted along the number of samples. A straight-line solution 320 that best fits all of the graphed data points 312, which shows how the standard deviation decreases as a function of sample size.

Equation (2) produces the best fit straight line 320 solution illustrated in FIG. 3B, which shows to be an accurate fit to the data points presented in Table 2.

$${σ}_{variation} = \frac{1}{\sqrt{2 n}} * \overline{σ} \qquad ( Eq . 2 )$$

where n is the sample population;
σ̅ is the mean value of the standard deviations calculated from the limited number of samples from many trials; and
σᵥₐᵣᵢₐₜᵢₒₙ is the variation of the standard deviations represented as the standard deviation of the standard deviations.

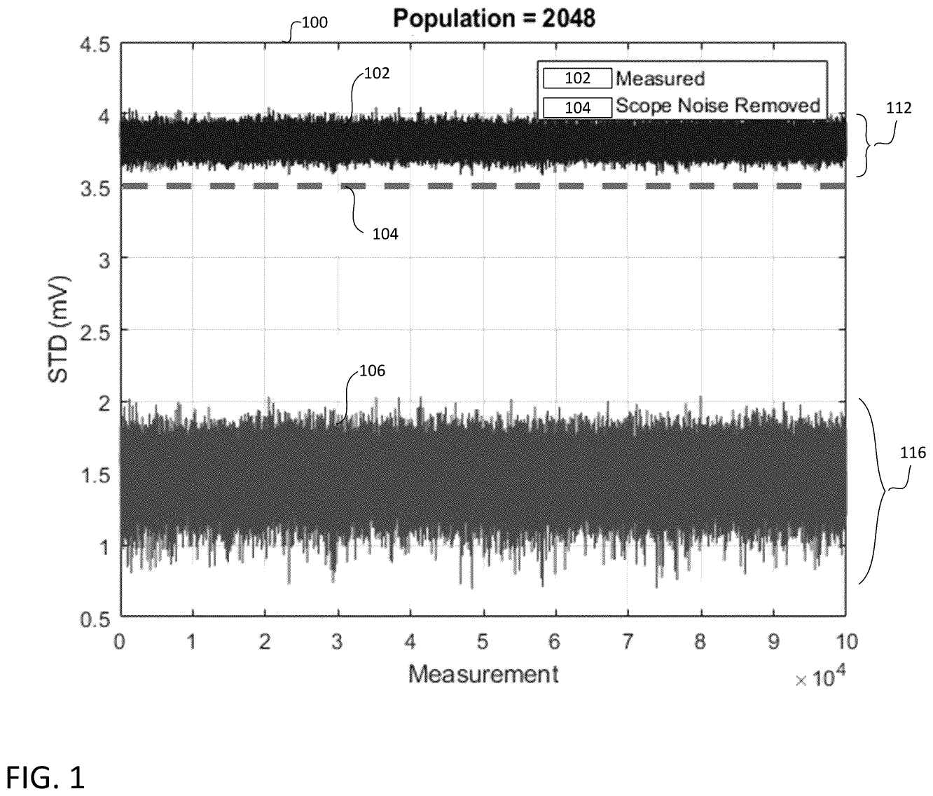

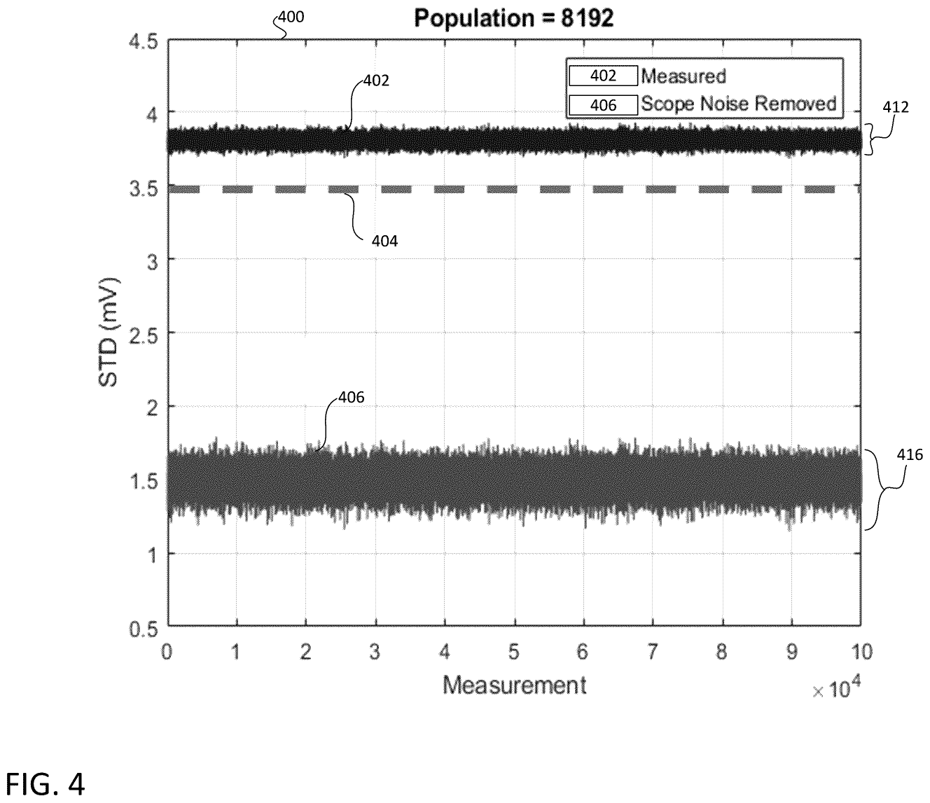

As previously mentioned, the instrument noise removal based on Equation (1) produces the standard deviation value for the noise of the DUT. This was already seen with reference to FIG. 1, which was the result of 100,000 repeated trials using Equation (1), and is seen again with reference to FIG. 4. The difference between FIGS. 1 and 4 is that the population sample size to gather the numbers to generate the display of FIG. 1 was 2048 and the population sample size to gather the numbers to generate the display of FIG. 4 was 8192. Other parameters are held the same, with Gaussian noise having a 0 mean, standard deviation being 1.5 mV for the DUT and 3.5 mV for the instrument. The details of FIG. 1 were explained above, but FIG. 4 is very similar in that the standard deviation of the measured noise 402 is graphed in the upper portion of the display, and the instrument noise 404 was determined to be 3.5 mV. Using Equation (1) to remove the instrument noise 404 from the measured noise 402 yields the standard deviation of the DUT 406. Note that, similar to the variations 112 and 116 of the respective noise 102, 106 (FIG. 1), a variation 412 of the measured noise 402 is similarly less than the variation 416 of the calculated DUT noise 406.

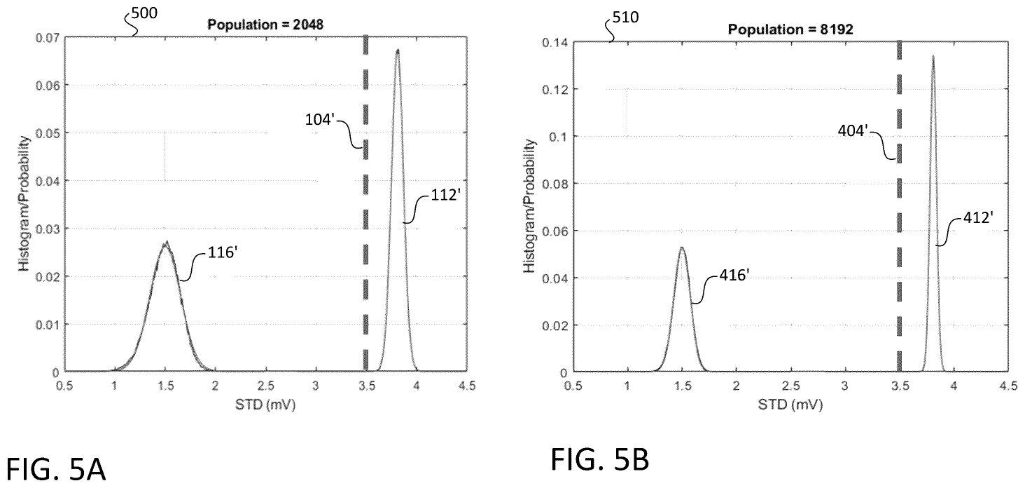

FIGS. 5A and 5B are statistics domain views 500, 510 of the same data used to produce FIGS. 1 and 4, respectively. For instance, the instrument noise 104′ and 404′ is still shown as approximately 3.5 mV. The standard deviations 112′ and 116′ are shown as counterparts to the deviations 112 and 116 of FIG. 1. Similarly, the standard deviations 412′ and 416′ are counterparts to the deviations 412 and 416 of FIG. 1. Note that the sample size impacts the variation, which follows the derivation of Equation (2). Comparing FIGS. 5A and 5B, as the population increases by four times (population of 8192 vs population of 2014), the standard deviation reduces by approximately \sqrt{4}=2 times. This is seen in the data of Table 2, below, as well as may be viewed graphically by the differences in FIGS. 5A and 5B.

TABLE 2
Sample population impact on the variation
of instrument noise removal

| | Standard deviation of | Standard deviation |
|---|---|---|
| | Std of DUT noise after | of Std of |
| Population | instrument noise removal | measured noise |
| 2048 | 0.153 | 0.059 |
| 8192 | 0.076 | 0.030 |

Embodiments of the disclosure use this relationship between sample population size and its resultant variation as a basis for adaptive removal of measurement instrument noise. First, Equation (1) can be re-written as:

$${σ}_{DUT} = \sqrt{{σ}_{meas}^{2} - {\overline{σ}}_{instrument}^{2}} = {σ}_{meas} \times \sqrt{1 - {( \frac{{\overline{σ}}_{instrument}}{{σ}_{meas}} )}^{2}} \qquad ( Eq . 3 )$$

As σ̅ᵢₙₛₜᵣᵤₘₑₙₜ is the characterization of instrument noise, described above, it is treated as a constant value from the instrument acquisition from run to run. Thus, the σ_{DUT} is a function of σₘₑₐₛ, based on Equation (1) and (3), and its derivative is derived in Equation (4):

$$\frac{d {σ}_{DUT}}{d {σ}_{meas}} = \frac{1}{2} \times \frac{1}{\sqrt{{σ}_{meas}^{2} - {\overline{σ}}_{instrument}^{2}}} \times 2 \times {σ}_{meas} = \frac{1}{\sqrt{1 - {( \frac{{\overline{σ}}_{instrument}}{{σ}_{meas}} )}^{2}}} \qquad ( Eq . 4 )$$

This derivative of Equation 4 reflects how much the variation of measured noise impacts the variation of the DUT noise after instrument noise removal. Since the measured noise is the combination of the DUT noise and the instrument noise, it is always true that:

σᵢₙₛₜᵣᵤₘₑₙₜ≤σₘₑₐₛ

The characterized instrument noise σ̅ᵢₙₛₜᵣᵤₘₑₙₜ is the mean of the σᵢₙₛₜᵣᵤₘₑₙₜ, when using to perform instrument noise removal, only when

σ̅ᵢₙₛₜᵣᵤₘₑₙₜ≤σₘₑₐₛ (Eq. 5)

Then Equation (1) can be applied under the condition of condition (5), based on Equation (4), to produce:

$$\frac{d {σ}_{DUT}}{d {σ}_{meas}} = \frac{1}{\sqrt{1 - {( \frac{{\overline{σ}}_{instrument}}{{σ}_{meas}} )}^{2}}} \geq 1 \qquad ( Eq . 6 )$$

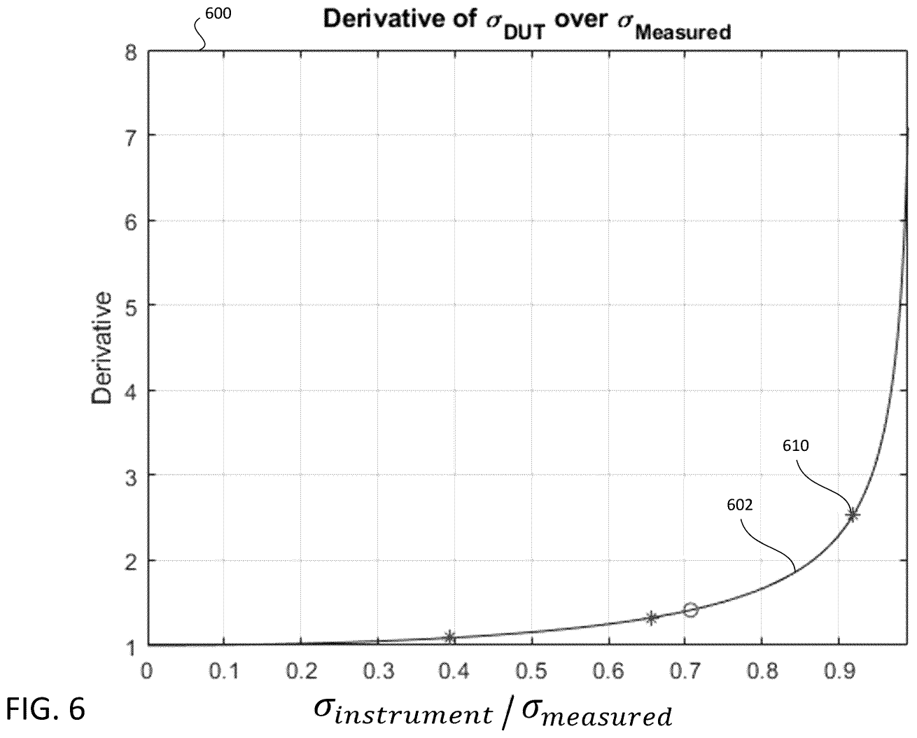

Thus, Equations (6) and Equation (4) reveal why and by how much the instrument noise removal amplifies the variation of DUT noise measurement. The ratio of instrument noise over measured noise determines the amplification factor based on Equation (4), as shown in FIG. 6, which is a graph 600 of the derivative of the DUT noise, after the instrument noise has been removed, over the ratio of the instrument noise to the measured noise. The instant values of the derivative are indicated by the function 602. For the case shown in Table 2, the derivative is 2.54 based on Equation (4), shown as the point 610 of the curve 602. The factor of 2.54 matches the ratio between the numbers in the rightmost two columns of Table 2.

The ratio between the instrument noise and the measured noise appears in both Equation (3) and Equation (4). Multiplying the two equations yields the following constraints:

$${σ}_{DUT} \times \frac{d {σ}_{DUT}}{d {σ}_{meas}} = {σ}_{meas} \qquad ( Eq . 7 )$$

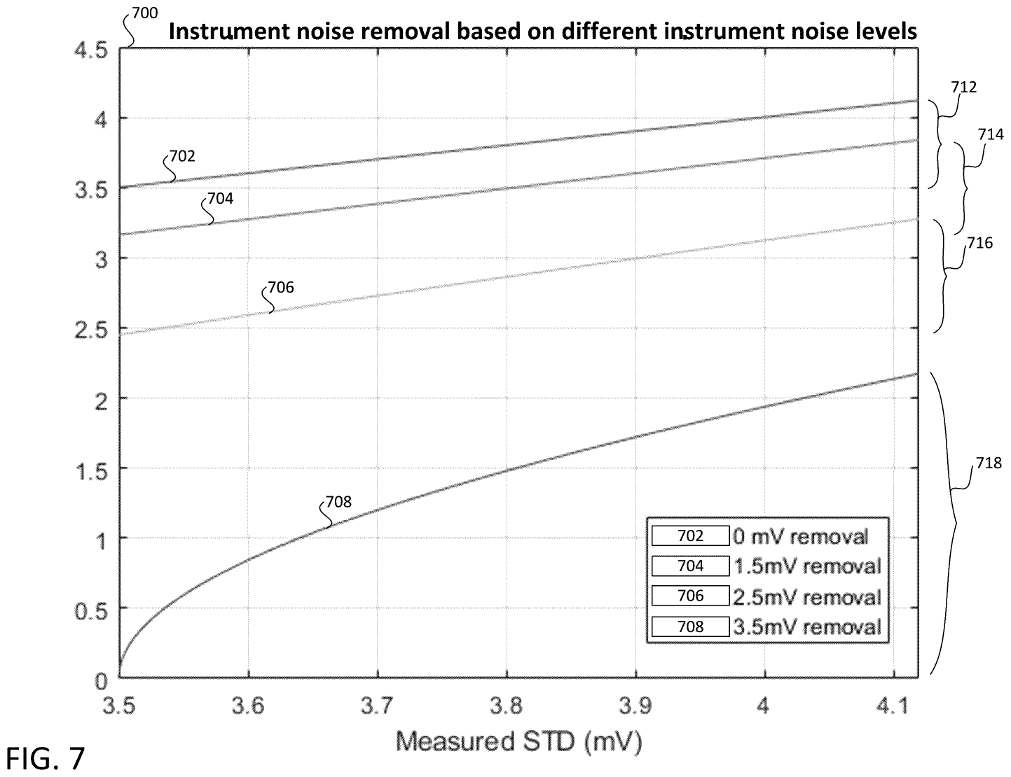

Therefore, for the same measured noise, when removing different amounts of instrument noise using the Equation (1), the constraint shown in the Equation (7) indicates that when more of the instrument noise is removed, the resulting DUT noise is lower, while the variation is higher; and, when less of the instrument noise is removed, the resulting DUT noise is higher, while the variation is lower. FIG. 7 is a graph that illustrates this phenomenon. For the same measured noise, as more instrument noise is removed based on Equation (1), the measured DUT noise decreases, while the variation increases. For example, trace 702 illustrates a 0 mV instrument removal according to Equation (1), while trace 702 illustrates a 1.5 mV removal. Similarly, traces 706 and 708 illustrate a 2.5 mV and a 3.5 mV removal, respectively. Notice the variations, which are referenced on the right hand side of the graph 700. The variation for the 0 mV removal, referenced as 712, is the smallest variation, while the variations 714, 716, and 718 get progressively larger as the amount of removed instrument noise increases.

Thus, the variation of the noise measurement is proportional to the inverse of the square root of the sample population, as seen in Equation (4). Higher sample populations help to reduce the variation. As shown in Table 2, when the population is increased by four times, the variation is decreased by approximately two times.

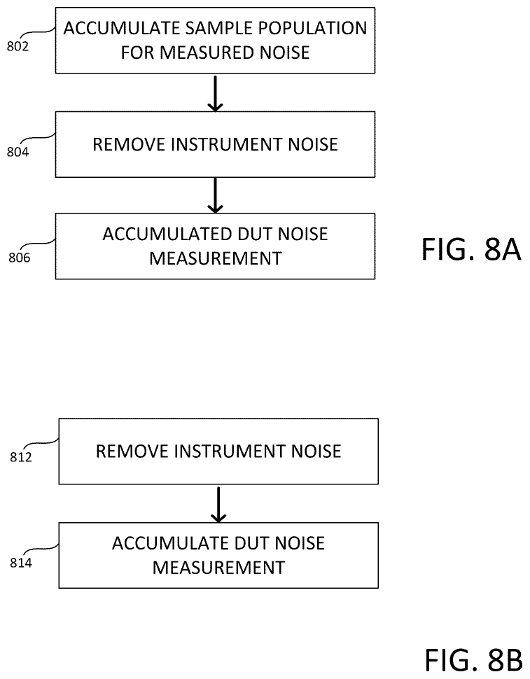

There are two possibilities to measure DUT noise when the sample population is limited for each acquisition run. As illustrated in FIG. 8A, the sample population may be accumulated in an operation 802 prior to removing the instrument noise in an operation 806, which yields the accumulated DUT noise measurement in operation 806. The other possibility is illustrated in FIG. 8B, where the instrument noise is removed in an operation 812 prior to accumulating the DUT noise measurement in an operation 814. The order of operations shown in FIG. 8A produces better, more accurate, results than does the order of operations shown in FIG. 8B. By accumulating the population for the measured noise in operation 802, the variation of the measured noise is reduced, which decreases the chances of smaller measured noise instances. Whereas, in the order of operations illustrated in FIG. 8B, for each noise measurement based on a single acquisition run, the variation could be large. Therefore, the chances of smaller measured noise instances is higher, causing larger amplification of variation based on the curve shown in FIG. 7.

Embodiments of the disclosure include an adaptive noise reduction method that produces better DUT noise measurements than present methods and devices. Equation (7) determines the constraints between lowering the DUT noise measurement and lowering the variation of DUT noise measurement if a constant amount of instrument noise is removed no matter what the measured noise value is.

The new adaptive instrument noise removal method instead adjusts the amount of instrument noise to be removed based on a ratio of the characterized instrument noise over the measured noise. When this ratio is high, less of the instrument noise is removed. But, when the ratio is low, more of the instrument noise is removed. This approach reduces the variation of the standard deviation of DUT noise after the instrument noise is removed, with a small increase of the standard deviation of DUT noise measurement.

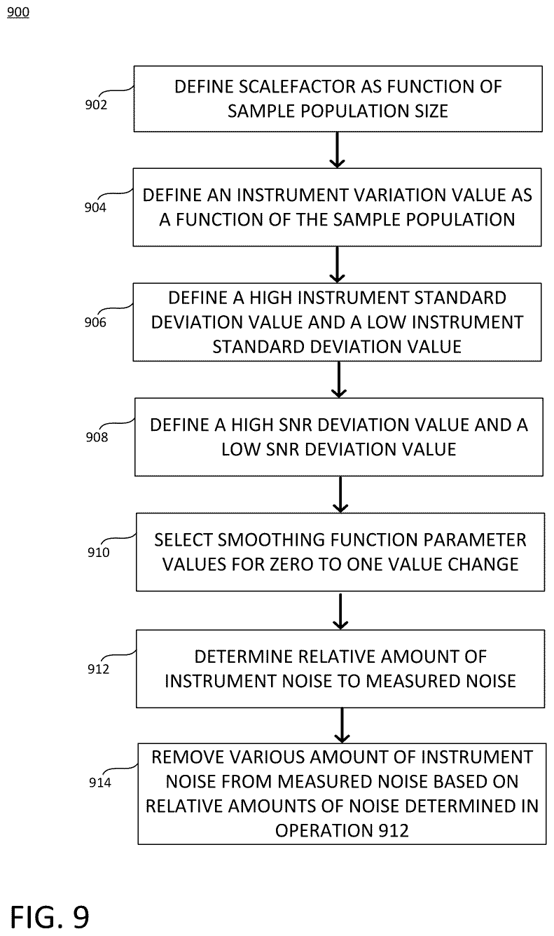

There are various ways to implement the adaptive instrument noise removal. One set of example operations are illustrated as flow 900 of FIG. 9.

A first operation 902 defines a scalefactor as a function of sample population size, as a larger sample population exhibits a lower standard of deviation of measured noise. For example, the operation 902 may ascribe a scalefactor as set out below, although other scale factors may be used depending on implementation details:

$$scaleFactor = \{ \begin{matrix}5 , & when samplePopulation \geq 2000 \\ 4 , & when 2000 > samplePopulation \geq 1000 \\ 3 , & when 1000 > samplePopulation\end{matrix} \qquad Defn . ( 1 )$$

Next, an operation 904 defines an instrument variation value, such as variationInst as function of the sample population and the characterized instrument noise based on Equation (2):

$$variationInst \frac{1}{\sqrt{2 n}} * {\overline{σ}}_{instτument} \qquad Defn . ( 2 )$$

Operation 906 defines two variables related to the standard deviation of the instrument, one for a high value and one for a low value:

σ_{Instrument}^{High}=σ̅_{Instrument}+scaleFactor×variationInst

σ_{Instrument}^{Low}=σ̅_{Instrument}+scaleFactor×variationInst Defn. (4)

Note that different scaleFactor values can be used for the high and the low instrument noise values. The scaleFactor values can also be different values than those specified in operation 902.

An operation 908 defines a low and a high Signal to Noise Ratio (SNR) deviation values, such as:

σ_{Snr}^{High}=\sqrt{σ^{High}_{Instrument}²−σ̅ᵢₙₛₜᵣᵤₘₑₙₜ²}

σ_{Snr}^{Low}=scaleFactor×variationInst Defn. (4)

With regard to Definition 4, note that yet even different scaleFactor values than those specified in Step 1 and Step 3 can be used in Definition 4.

Operation 910 accepts values for a smoothing function having a value change from 0 to 1 so that a user, or developer, may choose parameters to shape a smoothing function. For example, the smoothing function may be a normalized function over the following modified Sigmoid function:

$$y ( x ) = 1 - \frac{1}{1 + {e}^{( - ( x - a ) \times b )}} \qquad Modified Sigmoid Function ( 1 )$$

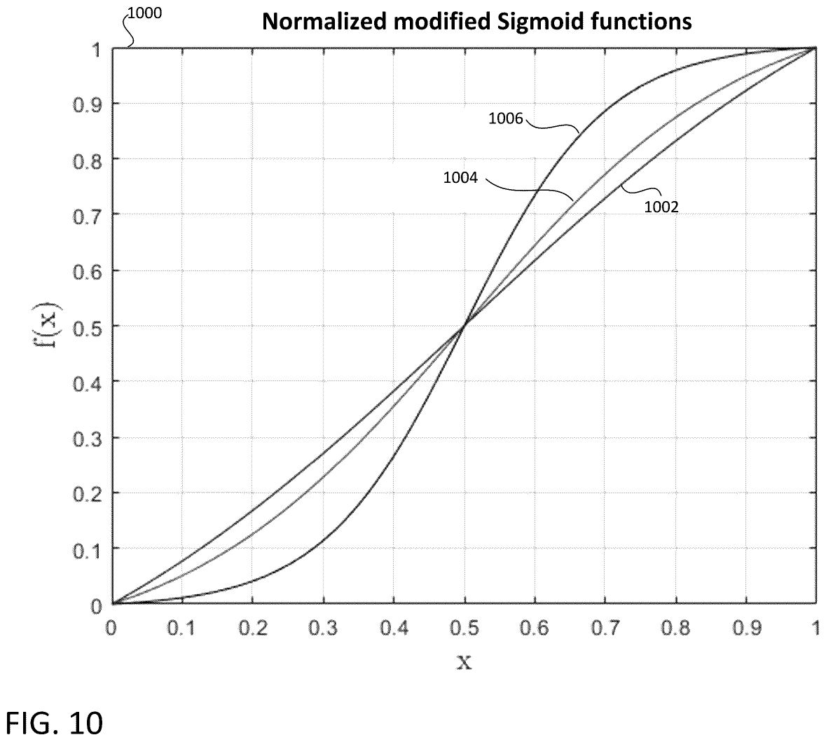

FIG. 10 is a graph 1000 that illustrates an example of how three different parameter choices affect the outcome of Function 1. In each of the functions, parameter a is selected to be 0.5. Then, Function 1 with a parameter b of 3 produces the function trace 1002, using a parameter b of 5 produces the function trace 1004, and using a parameter b of 10 produces function trace 1006. So, by choosing different parameter variables, the shape of a smoothing function is chosen.

To apply the smoothing function illustrated in FIG. 10 to embodiments of the disclosure, first, define x as:

$$x = \frac{{σ}_{meas} - {σ}_{Instrument}^{Low}}{{σ}_{Instrument}^{High} - {σ}_{Instrument}^{Low}} \qquad Defn . ( 5 )$$

Then, define p as the output of the normalized modified Sigmoid Function 1 with x as the input variable. The σ_{Interp} is the value obtained from the following interpolation:

σ_{Interp}=(1−p)×σ_{Snr}^{Low}+p×σ_{Snr}^{High} (Eq. 8)

Putting this all together, embodiments of the disclosure generate a measured output for the standard deviation of the DUT noise that depends on an amount of measured noise compared to the instrument noise. In other words, the noise measurement is adaptive, as set forth below:

$$Adaptive Output : {σ}_{DUT} = \{ \begin{matrix}\sqrt{{σ}_{meas}^{2} - {\overline{σ}}_{instrument}^{2}} , when {σ}_{meas} \geq {σ}_{Instrument}^{High} \\ {σ}_{Interp} , when {σ}_{Instrument}^{Low} < {σ}_{meas} < {σ}_{Instrument}^{High} \\ {σ}_{Snr}^{Low} , when {σ}_{meas} \leq {σ}_{Instrument}^{Low}\end{matrix}$$

As seen in the Adaptive Output equation above, embodiments of the disclosure use three different ways to compensate for instrument noise that depend on a ratio of instrument noise to total noise. With reference to FIG. 9, the ratio of instrument noise to measured noise is determined in an operation 912. When the amount of instrument noise compared to the measured noise, which, as described above includes both instrument noise and noise from the DUT, is low, then all of the instrument noise is subtracted out from the measured noise. On the other hand, when the amount of instrument noise compared to the total noise is relatively high, then the measured output is determined using Definition 4, and the output is set to the low SNR deviation value. If the amount of instrument noise is in between these two extremes, then the measured output is an interpolated value as shown in Equation 8. This removal of instrument noise based on the relative amount of instrument noise to the total noise is captured in operation 914 of FIG. 9.

Test results prove that the adaptive noise removal according to embodiments of the disclosure perform better than present methods. For a numerical example that looks at the mean value and the standard deviation value (variation) of the standard deviation of the DUT noise after instrument noise removal, three methods are compared:
Method 1: Remove the full amount of characterized instrument noise using Equation (1);
Method 2: Remove 95% of the characterized instrument noise using Equation (2); and
Method 3: Adaptive instrument noise removal using the Adaptive Output described above and referenced as operation 914, where the amount of instrument noise removed from the DUT measured noise is dependent on the amount of instrument noise compared to the amount of total noise.

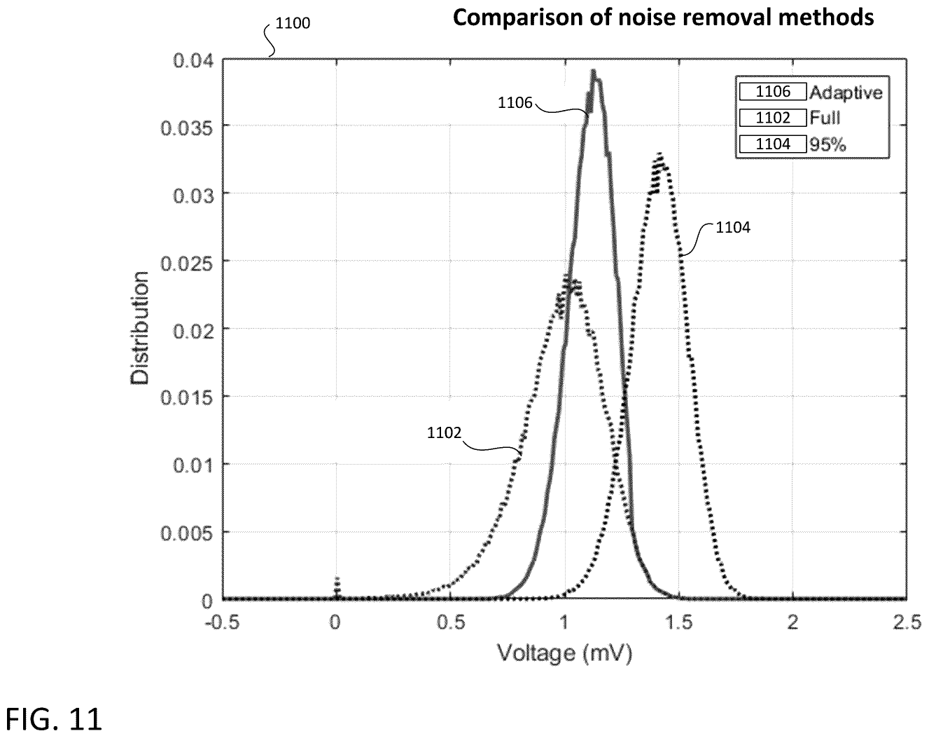

In this example, assume that instrument noise is 3.2 mV, the DUT noise is 1.0 mV, and sample population is 2048. The result is shown in Table 3 and FIG. 11.

TABLE 3
Comparison between instrument noise removal methods

| | | Standard deviation |
|---|---|---|
| Method | Mean of σ_{DUT} | (variation) of σ_{DUT} |
| (1) Full | 0.98 | 0.19 |
| (2) 95% | 1.41 | 0.13 |
| (3) Adaptive | 1.11 | 0.11 |

The results of Table 3 and the graph 1100 of FIG. 11 show that the adaptive instrument noise removal method reduces the variation of the DUT noise significantly, with a small increase of the mean of the DUT noise comparing to the Method 1. The adaptive Method 3, labeled as reference 1106 in FIG. 11, has a lower mean value as well as a lower variation compared to the Method 2, which is labeled as reference 1104. Both Method 2 (1104) and Method 3 (1106) avoid hitting 0 as the DUT noise, which is an error condition described above, whereas Method 1 hits the 0 value, as seen in reference 1102 in FIG. 11.

This disclosure introduces a new adaptive instrument noise removal method based on the analysis on the noise variation as a function of the sample population, and the derived formula that determines how the instrument noise removal amplifies variation. A numerical example shows that the new method can significantly reduce the DUT nose measurement variation after instrument noise removal with a small increase of the DUT noise mean value. This method can be used for vertical noise removal, it can also be used to remove the instrument noise on jitter measurement.

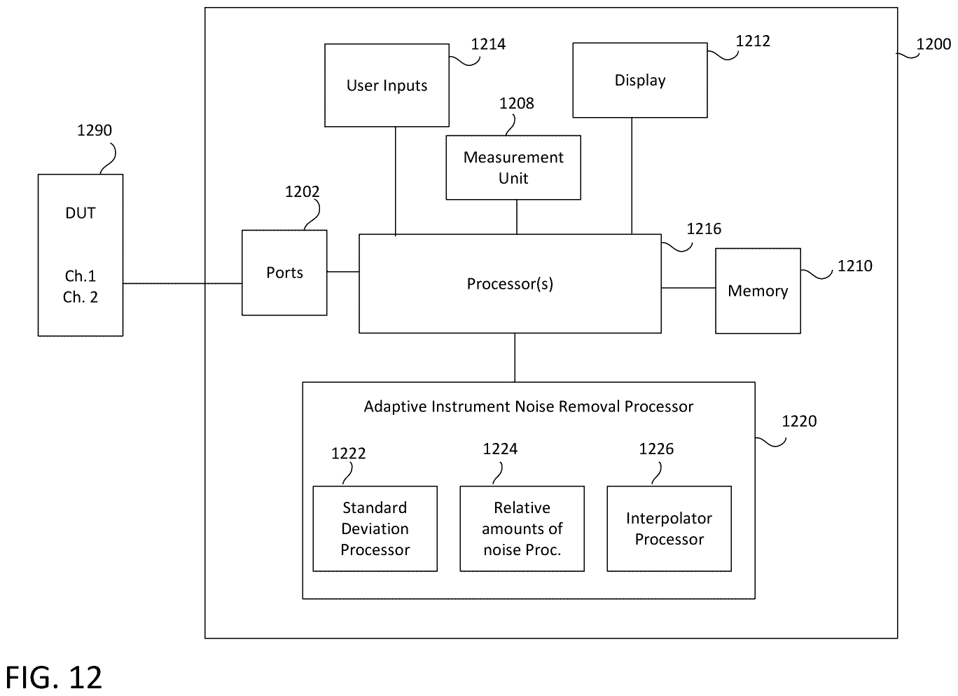

Embodiments of the disclosure operate on particular hardware and/or software to implement the above-described noise removal operations. FIG. 12 is a block diagram of an example test and measurement instrument 1200, such as an oscilloscope or other instrument for implementing embodiments of the disclosure disclosed herein. The test and measurement instrument 1200 includes one or more ports 1202, which may be any signaling medium. The ports 1202 may include receivers, transmitters, and/or transceivers. Each port 1202 is a channel of the test and measurement instrument 1200. The ports 1202 are coupled with one or more processors 1216 to process the signals and/or waveforms received at the ports 1202 from one or more devices under test (DUTs) 1290. In some embodiments the ports accept multiple signals from the DUT 1290, or from one or more DUTs. Although a two-signal DUT 1290 is illustrated in FIG. 12, the test and measurement instrument 1200 may accept any number of input signals up to the number of ports 1202. Also, although only one processor 1216 is shown in FIG. 12 for ease of illustration, as will be understood by one skilled in the art, multiple processors 1216 of varying types may be used in combination in the instrument 1200, rather than a single processor 1216.

The ports 1202 can also be connected to a measurement unit 1208 in the test instrument 1200. The measurement unit 1208 can include any component capable of measuring aspects (e.g., voltage, amperage, amplitude, power, energy, noise, jitter, etc.) of a signal received via ports 1202. The test and measurement instrument 1200 may include additional hardware and/or processors, such as conditioning circuits, analog to digital converters, and/or other circuitry to convert a received signal to a waveform for further analysis. The resulting waveform can then be stored in a memory 1210, as well as displayed on a display 1212.

The one or more processors 1216 may be configured to execute instructions from the memory 1210 and may perform any methods and/or associated steps indicated by such instructions, such as displaying and modifying the input signals received by the instrument. The memory 1210 may be implemented as processor cache, random access memory (RAM), read only memory (ROM), solid state memory, hard disk drive(s), or any other memory type. The memory 1210 acts as a medium for storing data, such as acquired sample waveforms, computer program products, and other instructions.

User inputs 1214 are coupled to the processor 1216. User inputs 1214 may include a keyboard, mouse, touchscreen, and/or any other controls employable by a user to set up and control the instrument 1200. User inputs 1214 may include a graphical user interface or text/character interface operated in conjunction with the display 1212. The user inputs 1214 may receive remote commands or commands in programmatic form, either on the instrument 1200 itself, or from a remote device. The display 1212 may be a digital screen, a cathode ray tube-based display, or any other monitor to display waveforms, measurements, and other data to a user. While the components of test instrument 1200 are depicted as being integrated within test and measurement instrument 1200, it will be appreciated by a person of ordinary skill in the art that any of these components can be external to test instrument 1200 and can be coupled to test instrument 1200 in any conventional manner (e.g., wired and/or wireless communication media and/or mechanisms). For example, in some embodiments, the display 1212 may be remote from the test and measurement instrument 1200, or the instrument may be configured to send output to a remote device in addition to displaying it on the instrument 1200. In further embodiments, output from the measurement instrument 1200 may be sent to or stored in remote devices, such as cloud devices, that are accessible from other machines coupled to the cloud devices.

The instrument 1200 may include an adaptive instrument noise removal processor 1220, which may be a separate processor from the one or more processors 1216 described above, or the functions of the principal component processor 1220 may be integrated into the one or more processors 1216. Additionally, the adaptive instrument noise removal processor 1220 may include separate memory, use the memory 1210 described above, or any other memory accessible by the instrument 1200. The adaptive instrument noise removal processor 1220 may include specialized processors or operations to implement the functions described above. For example, the adaptive instrument noise removal processor 1220 may include a standard deviation processor 1222 used to determine standard deviations of noise measurements made by the instrument 1220. Further, a processor 1224 may determine relative amounts of noise between the instrument noise and the measured noise, so that the adaptive instrument noise removal processor 1220 can determine which of the adaptive output methods to use to compensate for instrument noise. The adaptive instrument noise removal processor 1220 may further include an interpolator processor 1226 that is used to generate the smoothing, interpolated curve. This processor 1226 would be active for the middle case of the adaptive noise processing, where the instrument noise is neither a high percentage or low percentage of the overall measured noise.

Any or all of the components of the adaptive instrument noise removal processor 1220, including the standard deviation processor 1222, relative amounts of noise processor 1224, and the interpolator processor 1226 may be embodied in one or more separate processors, and the separate functionality described herein may be implemented as specific pre-programmed operations of a special purpose or general purpose processor. Further, as stated above, any or all of the components or functionality of the adaptive instrument noise removal processor 1220 may be integrated into the one or more processors 1216 that operate the instrument 1200.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the instrument of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

Additionally, this written description makes reference to particular features. It is to be understood that the disclosure in this specification includes all possible combinations of those particular features. For example, where a particular feature is disclosed in the context of a particular aspect, that feature can also be used, to the extent possible, in the context of other aspects.

Also, when reference is made in this application to a method having two or more defined steps or operations, the defined steps or operations can be carried out in any order or simultaneously, unless the context excludes those possibilities.

Although specific aspects of the disclosure have been illustrated and described for purposes of illustration, it will be understood that various modifications may be made without departing from the spirit and instrument of the disclosure. Accordingly, the disclosure should not be limited except as by the appended claims.

### EXAMPLES

Illustrative examples of the disclosed technologies are provided below. An embodiment of the technologies may include one or more, and any combination of, the examples described below.

Example 1 is a test and measurement instrument including an input configured to receive an input signal from a device under test (DUT), an output display, and one or more processors configured to execute code that causes the one or more processors to measure a noise component of the input signal, compensate the measured noise component based on a measurement population and a relative amount of noise generated by the test and measurement instrument and a total noise measurement, and produce the compensated measured noise component as a noise measurement on the output display.

Example 2 is a test and measurement instrument according to Example 1, in which the one or more processors are configured to compensate the measured noise component by removing all of the characterized noise generated by the test and measurement instrument from the noise measurement only when the measured noise component of the input signal is greater than a threshold determined by the measurement population and a ratio of the instrument noise compared to the measured noise component of the input signal.

Example 3 is a test and measurement instrument according to any of the preceding Examples, in which the measured noise component of the input signal includes noise from the DUT and noise generated by the test and measurement instrument.

Example 4 is a test and measurement instrument according to any of the preceding Examples, in which the one or more processors are configured to compensate the measured noise component by generating an interpolation curve and applying the curve to the amount of noise removed.

Example 5 is a test and measurement instrument according to Example 4, in which the interpolation curve is a function spanning a low signal to noise deviation value to a high signal to noise deviation value of the instrument.

Example 6 is a test and measurement instrument according to Example 4, in which the one or more processors are configured to compensate the measured noise component by the applied interpolation curve only when the measured noise component is between a low threshold and a high threshold.

Example 7 is a test and measurement instrument according to Example 6, in which the low threshold and the high threshold are determined by the measurement population and the ratio of the instrument noise compared to the measured noise component of the input signal.

Example 8 is a test and measurement instrument according to any of the preceding Examples, in which the one or more processors are configured to compensate the measured noise component by setting the noise measurement to a scaled value of an instrument variation value.

Example 9 is a test and measurement instrument according to Example 8, in which the one or more processors are configured to set the noise measurement to a scaled value of an instrument variation value only when the measured noise component is below a low threshold.

Example 10 is a the test and measurement instrument according to any of the preceding Examples, in which the one or more processors are configured to compensate the measured noise component by setting the noise measurement to

$$scaleFactor * \frac{1}{\sqrt{2 n}} * {\overline{σ}}_{instrument} ,$$

where n is a number of samples to be measured in the input signal, σ̅ᵢₙₛₜᵣᵤₘₑₙₜ is the characterized noise generated by the test and measurement instrument, and scaleFactor is a scaling factor based on the relative size of n.

Example 11 is a method of generating a noise measurement in a measurement instrument, including accepting an input signal from a device under test (DUT), measuring an amount of noise in the input signal, in which measuring the amount of noise includes measuring an amount of noise generated by the DUT and an amount of noise generated by the measurement instrument, and compensating the measured amount of noise based on the measurement population and a relative amount of noise generated by the measurement instrument to the measured amount of noise.

Example 12 is a method according to Example 11, in which compensating the measured amount of noise comprises removing all of the characterized noise generated by the measurement instrument only when the measured noise component of the input signal is greater than a threshold.

Example 13 is a method according to Example 12, in which the threshold amount is determined by a number of noise measurements and a ratio of the instrument noise compared to the measured amount of noise in the input signal.

Example 14 is a method according to any of the preceding Example methods, in which compensating the measured amount of noise includes generating an interpolation curve; and applying the curve to the amount of noise removed.

Example 15 is a method according to Example 14, in which the interpolation curve is applied to the amount of noise removed only when the measured noise component is between a low threshold and a high threshold.

Example 16 is a method according to Example 15, in which the low threshold and the high threshold are determined by the number of noise measurements and the ratio of the instrument noise compared to the measured noise component of the input signal.

Example 17 is a method according to any of the preceding Example methods, in which compensating the measured noise comprises setting the noise measurement to a scaled value of an instrument variation value.

Example 18 is a method according to Example 17 in which the noise measurement is set to the scaled value of the instrument variation value only when the measured noise component is below a low threshold.

Example 19 is a method according to any of the preceding Example methods, in which compensating the measured noise comprises setting the noise measurement to

$$scaleFactor * \frac{1}{\sqrt{2 n}} * {\overline{σ}}_{instrument} ,$$

where n is a number of samples to be measured in the input signal, σ̅ᵢₙₛₜᵣᵤₘₑₙₜ is the noise generated by the test and measurement instrument, and scaleFactor is a scaling factor based on the relative size of n.

The previously described versions of the disclosed subject matter have many advantages that were either described or would be apparent to a person of ordinary skill. Even so, these advantages or features are not required in all versions of the disclosed apparatus, systems, or methods.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

Although specific examples of the invention have been illustrated and described for purposes of illustration, it will be understood that various modifications may be made without departing from the spirit and instrument of the invention. Accordingly, the invention should not be limited except as by the appended claims.

We claim:

1. A test and measurement instrument, comprising:
an input configured to receive an input signal from a device under test (DUT);
an output display; and
one or more processors configured to execute code that causes the one or more processors to:
measure a noise component of the input signal,
compensate the measured noise component based on a measurement population and a relative amount of noise generated by the test and measurement instrument and a total noise measurement, and
produce the compensated measured noise component as a noise measurement on the output display.

2. The test and measurement instrument according to claim 1, in which the one or more processors are configured to compensate the measured noise component by removing all of the characterized noise generated by the test and measurement instrument from the noise measurement only when the measured noise component of the input signal is greater than a threshold determined by the measurement population and a ratio of the instrument noise compared to the measured noise component of the input signal.

3. The test and measurement instrument according to claim 1, in which the measured noise component of the input signal includes noise from the DUT and noise generated by the test and measurement instrument.

4. The test and measurement instrument according to claim 1, in which the one or more processors are configured to compensate the measured noise component by generating an interpolation curve and applying the curve to the amount of noise removed.

5. The test and measurement instrument according to claim 4, in which the interpolation curve is a function spanning a low signal to noise deviation value to a high signal to noise deviation value of the instrument.

6. The test and measurement instrument according to claim 4, in which the one or more processors are configured to compensate the measured noise component by the applied interpolation curve only when the measured noise component is between a low threshold and a high threshold.

7. The test and measurement instrument according to claim 6, in which the low threshold and the high threshold are determined by the measurement population and the ratio of the instrument noise compared to the measured noise component of the input signal.

8. The test and measurement instrument according to claim 1, in which the one or more processors are configured to compensate the measured noise component by setting the noise measurement to a scaled value of an instrument variation value.

9. The test and measurement instrument according to claim 8, in which the one or more processors are configured to set the noise measurement to a scaled value of an instrument variation value only when the measured noise component is below a low threshold.

10. The test and measurement instrument according to claim 1, in which the one or more processors are configured to compensate the measured noise component by setting the noise measurement to
$$scaleFactor * \frac{1}{\sqrt{2 n}} * {\overline{σ}}_{instrument} ,$$
where n is a number of samples to be measured in the input signal, σ̅ᵢₙₛₜᵣᵤₘₑₙₜ is the characterized noise generated by the test and measurement instrument, and scaleFactor is a scaling factor based on the relative size of n.

11. A method of generating a noise measurement in a measurement instrument, comprising:
accepting an input signal from a device under test (DUT);
measuring an amount of noise in the input signal, in which measuring the amount of noise includes measuring an amount of noise generated by the DUT and an amount of noise generated by the measurement instrument; and
compensating the measured amount of noise based on the measurement population and a relative amount of noise generated by the measurement instrument to the measured amount of noise.

12. The method of claim 11, in which compensating the measured amount of noise comprises removing all of the characterized noise generated by the measurement instrument only when the measured noise component of the input signal is greater than a threshold.

13. The method of claim 12, in which the threshold amount is determined by a number of noise measurements and a ratio of the instrument noise compared to the measured amount of noise in the input signal.

14. The method of claim 11 in which compensating the measured amount of noise comprises:
generating an interpolation curve; and
applying the curve to the amount of noise removed.

15. The method of claim 14, in which the interpolation curve is applied to the amount of noise removed only when the measured noise component is between a low threshold and a high threshold.

16. The method of claim 15, in which the low threshold and the high threshold are determined by the number of noise measurements and the ratio of the instrument noise compared to the measured noise component of the input signal.

17. The method according to claim 11, in which compensating the measured noise comprises setting the noise measurement to a scaled value of an instrument variation value.

18. The method according to claim 17, in which the noise measurement is set to the scaled value of the instrument variation value only when the measured noise component is below a low threshold.

19. The method according to claim 11, in which compensating the measured noise comprises setting the noise measurement to
$$scaleFactor * \frac{1}{\sqrt{2 n}} * {\overline{σ}}_{instrument} ,$$
where n is a number of samples to be measured in the input signal, σ̅ᵢₙₛₜᵣᵤₘₑₙₜ is the noise generated by the test and measurement instrument, and scaleFactor is a scaling factor based on the relative size of n.
